(19) United States
(12) Patent Application Publication
(10) Pub. No.: US 2024/0021477 A1
(43) Pub. Date: Jan. 18, 2024

(54) METHOD OF MANUFACTURING SEMICONDUCTOR CHIP INCLUDING DICING SUBSTRATE

(71) Applicant: SK hynix Inc., Icheon-si Gyeonggi-do (KR)

(72) Inventor: Mingyu KANG, Icheon-si Gyeonggi-do (KR)

(73) Assignee: SK hynix Inc., Icheon-si Gyeonggi-do (KR)

(21) Appl. No.: 18/073,931

(22) Filed: Dec. 2, 2022

(30) Foreign Application Priority Data
Jul. 13, 2022 (KR) 10-2022-0086556

(51) Int. Cl. H01L 21/78

(52) U.S. Cl. CPC H01L 21/78; H01L 21/304

(57) ABSTRACT

A method of manufacturing a semiconductor chip includes a process of dicing a substrate. A first notch portion and a second notch portion that are spaced apart from each other are formed on a surface of the substrate along a dicing line. Modified patterns are formed within the substrate. The substrate is diced by propagating cracks into the substrate from the modified patterns. The first notch portion and the second notch portion are formed to penetrate an organic matter layer of the substrate.

### CROSS-REFERENCE TO RELATED APPLICATION

The present application claims priority under 35 U.S.C. § 119(a) to Korean application number 10-2022-0086556, filed in the Korean Intellectual Property Office on Jul. 13, 2022, the entire disclosure of which is incorporated herein by reference.

### BACKGROUND

The present disclosure relates to a semiconductor technology and, more particularly, to a method of manufacturing a semiconductor chip, including dicing a substrate.

Semiconductor devices or integrated circuits are integrated on a substrate, such as a wafer. A plurality of semiconductor chips may be separated from the substrate on which the semiconductor devices have been integrated by dicing the substrate. The semiconductor chips may include the semiconductor devices. In the process of dicing the substrate, to reduce a substrate consumption portion that is consumed for the dicing, attempts to replace a blade dicing process with dicing processes using a laser are suggested. In the dicing process using the laser, a non-dicing failure where the semiconductor chips have not been diced may occur. To reduce non-dicing failures, various forms of attempts are being made.

### SUMMARY

In accordance with the present disclosure, a method of manufacturing a semiconductor chip may include: forming, on a first surface of a substrate, a first notch portion and a second notch portion that are spaced apart from each other along a first dicing line; forming modified patterns within the substrate; and dicing the substrate by propagating cracks into the substrate from the modified patterns.

Also in accordance with the present disclosure, a method of manufacturing a semiconductor chip may include: forming a substrate which includes a semiconductor base in which first and second scribe lane regions intersect, an active layer that is formed on the semiconductor base, and an organic matter layer; forming a first notch portion and a second notch portion that are spaced apart from each other in the first scribe lane region and that penetrate the organic matter layer; forming modified patterns within the semiconductor base along the first scribe lane region; and dicing the substrate by propagating cracks into the substrate from the modified patterns.

### BRIEF DESCRIPTION OF THE DRAWINGS

FIGS. 1 to 14 are diagrams illustrating a method of manufacturing a semiconductor chip according to the present disclosure.

FIGS. 15 to 22 are diagrams illustrating methods of forming notch portions in the method of manufacturing a semiconductor chip according to the present disclosure.

FIGS. 23 and 24 are process flowcharts illustrating methods of manufacturing a semiconductor chip according to the present disclosure.

FIG. 25 is a block diagram illustrating an electronic system using a memory card including a semiconductor chip manufactured according to the present disclosure.

FIG. 26 is a block diagram illustrating an electronic system including a semiconductor chip manufactured according to the present disclosure.

### DETAILED DESCRIPTION

Terms used in the writing of an example of this application are terms selected by taking into consideration their functions. The meanings of the terms may be different depending on a user or operator's intention or practice. The meanings of terms used herein follow defined definitions if the meanings of the terms have been specifically defined in this specification, and may be construed as having meanings commonly recognized by those skilled in the art if the meanings of the terms have not been specifically defined.

In the writing of the present disclosure, terms, such as a “first” and a “second”, a “side”, a “top”, and a “bottom or lower”, are used to distinguish between members, and are not used to limit the members themselves or to mean a specific sequence of the members.

Semiconductor substrates may denote a semiconductor wafer on which electronic parts and elements have been integrated. Integrated circuits may be integrated on the semiconductor substrate. The semiconductor substrate may be diced into a plurality of semiconductor chips or a plurality of semiconductor dies.

A semiconductor chip may denote a memory chip in which memory, such as DRAM, SRAM, NAND flash, NOR flash, MRAM, ReRAM, FeRAM, or PcRAM, have been integrated. A semiconductor chip may denote a logic die, an ASIC chip, an application processor (AP), a graphic processing unit (GPU), a central processing unit (CPU), or a system on chip (SoC) in which logic circuits have been integrated on a semiconductor substrate.

A semiconductor chip may be an element that constitutes a semiconductor package or a semiconductor product. A semiconductor chip may be applied to an information communication device such as a portable terminal, bio or healthcare-related electronic devices, or wearable electronic devices. The semiconductor chip may be applied to the Internet of things (IoT).

Throughout this specification, same reference numerals may denote the same elements. Although not mentioned or described in a corresponding drawing, the same reference numerals or similar reference numerals may be described on the basis of another drawing. Furthermore, although a reference numeral is not indicated in a corresponding drawing, the reference numeral may be described on the basis of another drawing.

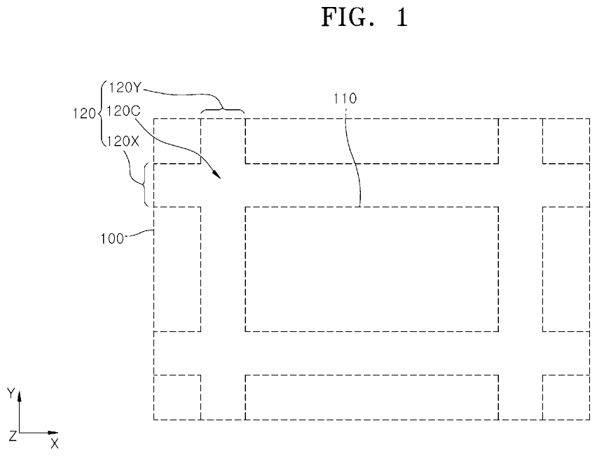

FIGS. 1 to 14 are schematic diagrams illustrating a method of manufacturing a semiconductor chip according to the present teachings. FIG. 1 is a schematic plane view illustrating a substrate 100 on which a method of manufacturing a semiconductor chip according to the present teachings will be performed. FIG. 1 may schematically illustrate a shape in which regions 110 and 120 of the substrate 100 have been disposed on an X-Y plane.

Referring to FIG. 1, the method of manufacturing a semiconductor chip may include process steps of separating the substrate 100 into individual semiconductor chips. The substrate 100 may have a wafer shape. The substrate 100 may be a device substrate on which memory devices or semiconductor devices, or integrated circuits have been integrated. The substrate 100 may include chip regions 110 and a scribe lane region 120. The scribe lane region 120 may be a region that is disposed between the chip region 110 and another chip region 110 that is adjacent to the chip region 110. The scribe lane region 120 may be a region that partitions the chip region 110 by surrounding the chip region 110.

The chip region 110 may be a region in which semiconductor devices, integrated circuits, or memory devices are integrated or disposed. The memory devices may be volatile memory devices, such as dynamic random access memory (DRAM). The memory devices may be nonvolatile memory devices, such as flash memory. The chip regions 110 may be regions that will be separated into individual semiconductor chips by a dicing process. The chip region 110 may be a region in which pattern density is relatively high. The scribe lane region 120 may be a region in which pattern density is relatively low.

The substrate 100 may include first scribe lane regions 120X and second scribe lane regions 120Y that intersect each other. The scribe lane region 120 may include the first scribe lane regions 120X and the second scribe lane regions 120Y, and may include cross regions 120C, that is, portions at which the first scribe lane regions 120X intersect the second scribe lane regions 120Y. The first scribe lane region 120X may extend in a first direction that will be an X axis direction in the X-Y plane. The second scribe lane region 120Y may extend in a second direction that will be a Y axis direction. The second direction may be a direction that intersects the first direction. When viewed in the X-Y plane, the chip region 110 may have a rectangular or oblong shape in which four corners of the chip region 110 are adjacent to the cross regions 120C.

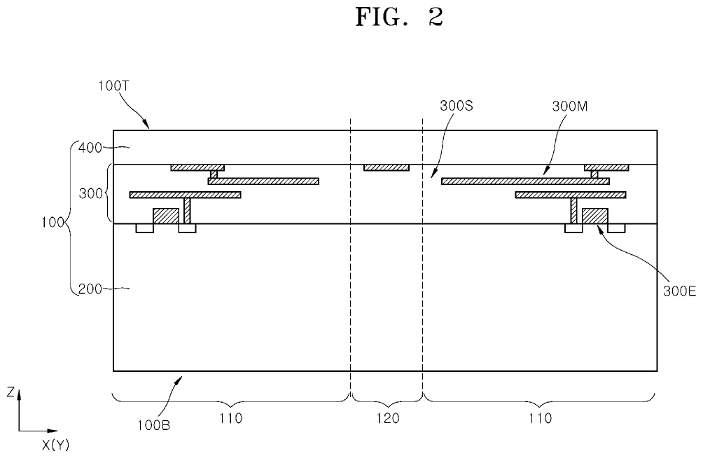

FIG. 2 is a schematic cross-sectional view illustrating a cross-sectional shape of the substrate 100 in FIG. 1.

Referring to FIG. 2, the substrate 100 may include a semiconductor base 200, an active layer 300, and an organic matter layer 400. The semiconductor base 200 may denote a semiconductor substrate or a semiconductor wafer that is composed of a semiconductor material. The semiconductor base 200 may include a semiconductor material, such as silicon (Si) or germanium (Ge). The semiconductor base 200 may include a compound semiconductor material, such as silicon carbide (SiC), gallium arsenide (GaAs), indium arsenide (InAs), or indium phosphorous (InP).

Electronic elements 300E that constitute a semiconductor device, a memory device, or an integrated circuit may be integrated on the semiconductor base 200. The electronic elements 300E may include transistor structures. The electronic elements 300E may be disposed in the chip region 110. The electronic elements 300E may constitute volatile memory devices or may constitute nonvolatile memory devices.

The active layer 300 may include a plurality of conductive layers 300M and a plurality of interlayer insulating layers 300S. The interlay insulating layer 300S may include an insulating material, such as silicon dioxide (SiO₂) or silicon nitride (Si₃N₄). The active layer 300 may include various types of material layers that constitute memory devices. The conductive layer 300M may include wire layers that constitute a semiconductor device, a memory device, or an integrated circuit. The interlay insulating layers 300S may include an insulating material that insulates wire layers from each other. The conductive layers 300M may include a gate layer, word lines, bit lines, or multi-layer metal wire layers that constitute a transistor structure or a memory device. The conductive layer 300M may be formed to have relatively high pattern density in the chip region 110, and may be formed to have relatively low pattern density in the scribe lane region 120. The conductive layers 300M that are disposed in the scribe lane region 120 may include test patterns or process monitoring patterns. The conductive layers 300M may include a metal material, such as aluminum (Al) or copper (Cu).

The organic matter layer 400 may be a layer that covers and protects the active layer 300. The organic matter layer 400 may include a polymeric layer. The organic matter layer 400 may include poly(imide-isoindoloquinazolinedione) (PIQ). A top surface of the organic matter layer 400 may provide a first surface 100T of the substrate 100. The substrate 100 may have a second surface 100B that is opposite to the first surface 100T. The second surface 100B of the substrate 100 may be the backside of the semiconductor base 200, which is opposite to the active layer 300.

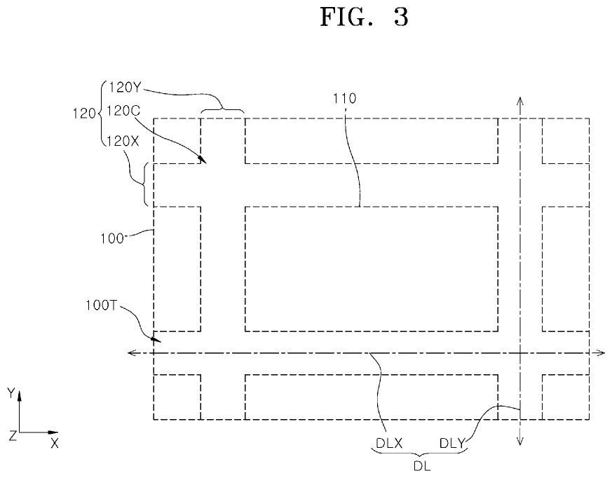

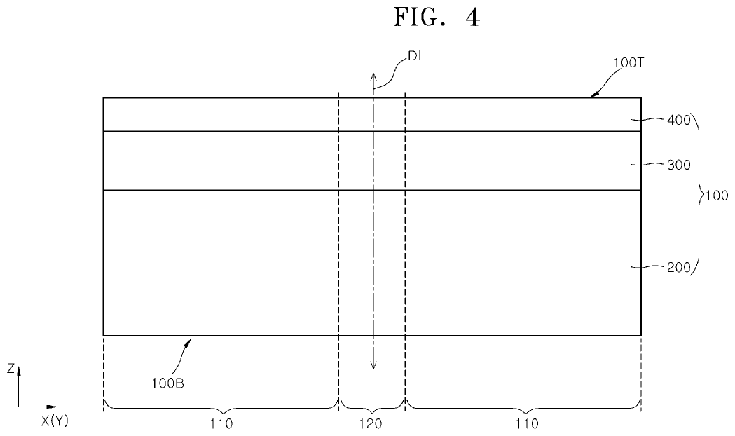

FIGS. 3 and 4 are a schematic plane view and a cross-sectional view illustrating a dicing line DL in a method of manufacturing a semiconductor chip according to the present teachings.

Referring to FIGS. 3 and 4, the scribe lane region 120 of the substrate 100 may be a region in which the substrate 100 is diced into individual semiconductor chips. The dicing lines DL that dices the substrate 100 may be set in a direction in which the scribe lane region 120 extends. The dicing line DL may denote a location at which the substrate 100 will be diced from the first surface 100T of the substrate 100 to the second surface 100B thereof. A first dicing line DLX may be set to extend along the first scribe lane region 120X. The first dicing line DLX may be set to indicate a first dicing direction and a first dicing location in the X axis direction. A second dicing line DLY may be set as a virtual line that extends along the second scribe lane region 120Y. The second dicing line DLY may be set to indicate a second dicing direction and a second dicing location in the Y axis direction.

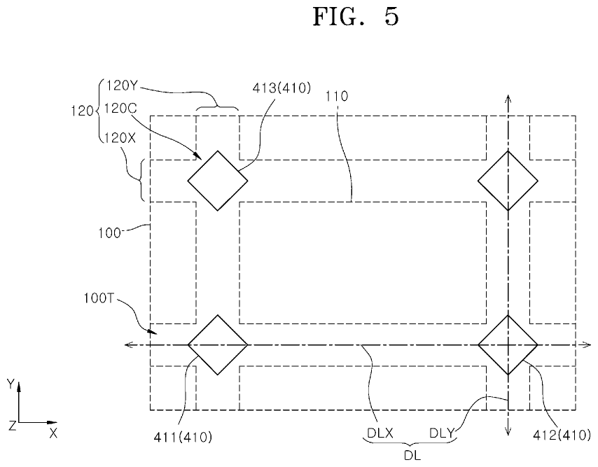

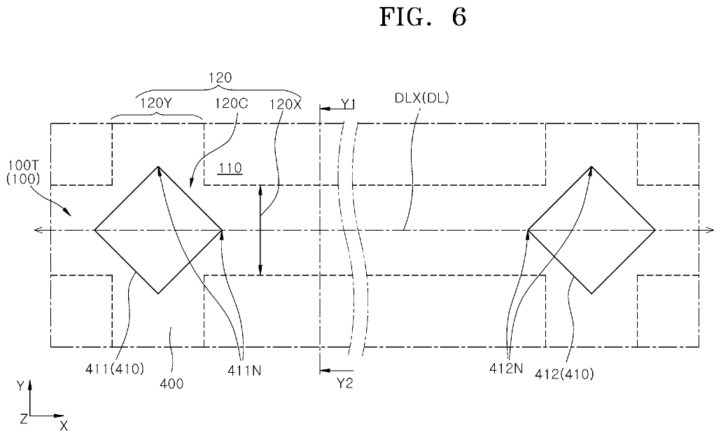

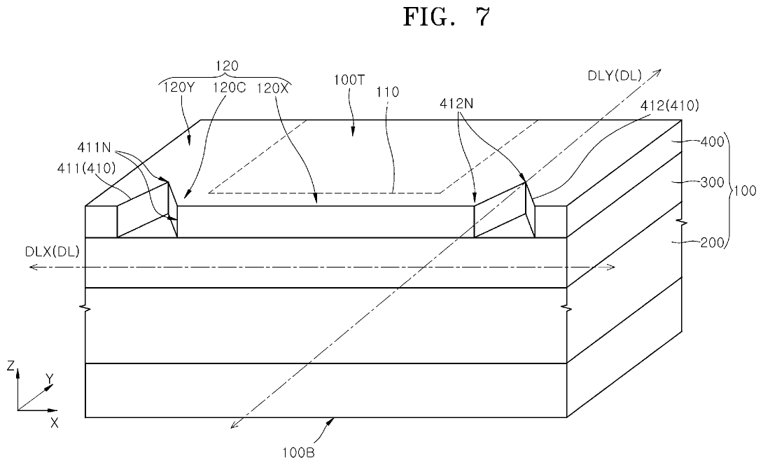

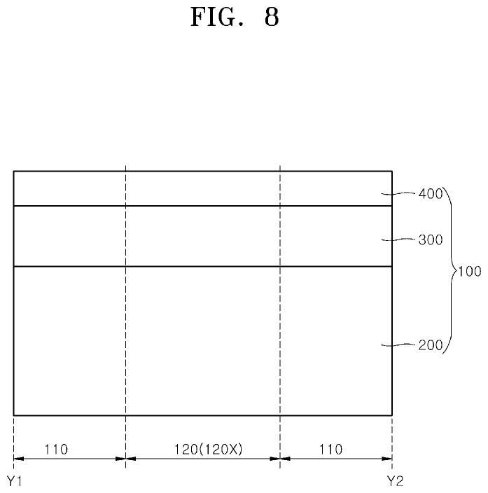

FIGS. 5 to 8 are schematic diagrams illustrating a step of forming notch portions 410 in a method of manufacturing a semiconductor chip according to the present teachings. FIG. 5 is a schematic plane view illustrating arrangement shapes of the notch portions 410 in the first surface 100T of the substrate 100. FIG. 6 is a schematic plane view illustrating that some plane shapes of the notch portions 410 in FIG. 5 have been enlarged. FIG. 7 is a schematic perspective view illustrating shapes of the notch portions 410 in FIG. 5. FIG. 8 is a schematic cross-sectional view illustrating a cross-sectional shape of the substrate 100 along a cutting plane line Y1-Y2 in FIG. 6.

Referring to FIG. 5, the notch portions 410 may be formed in the first surface 100T of the substrate 100. The notch portions 410 may be disposed in the first surface 100T of the substrate 100 in a way to be spaced apart from each other. Each of the notch portions 410 may have a groove shape having a given depth in the first surface 100T of the substrate 100. Some portions of the first surface 100T of the substrate 100 may be selectively removed, so that the notch portions 410 having concave shapes may be formed in the first surface 100T of the substrate 100.

The notch portions 410 may be formed to be disposed on the dicing line DL that has been set to indicate a location at which the substrate 100 will be diced. The notch portions 410 may be formed to be spaced apart from each other on the dicing line DL. The notch portions 410 may include a first notch portion 411 and a second notch portion 412 that are spaced apart from each other. The first notch portion 411 and the second notch portion 412 may be disposed to be spaced apart from each other along the first dicing line DLX. The first notch portion 411 and the second notch portion 412 may be spaced apart from each other in a first direction in which the first dicing line DLX extends, for example, the X axis direction. A third notch portion 413 that is spaced apart from the first and second notch portions 411 and 412 may be further formed while the first and second notch portions 411 and 412 are formed. The third notch portion 413 may be formed to be spaced apart from the first notch portion 411 along the second dicing line DLY that has been set to intersect the first dicing line DLX.

Each of the first notch portion 411 and the second notch portion 412 may be formed at a point at which the first dicing line DLX and the second dicing line DLY intersect. The notch portions 410 may be formed while being spaced apart from each other on the scribe lane region 120 of the substrate 100. The first notch portion 411 and the second notch portion 412 may be formed while being spaced apart from each other in the X axis direction in the first scribe lane region 120X. While the first notch portion 411 and the second notch portion 412 are formed, the third notch portion 413 may be further formed to be spaced apart from the first notch portion 411 in the Y axis direction on the second scribe lane region 120Y. The first notch portion 411, the second notch portion 412, and the third notch portion 413 may be formed to be disposed at the cross regions 120C, respectively, that is, crossing portions at which the first scribe lane region 120X and the second scribe lane region 120Y intersect.

Referring to FIG. 6, when viewed on the X-Y plane, the first notch portion 411 and the second notch portion 412 may be formed in the first surface 100T of the substrate 100 so that the first notch portion 411 and the second notch portion 412 have a first wedge-shaped portion 411N and a second wedge-shaped portion 412N that face each other, respectively. The first notch portion 411 and the second notch portion 412 may be formed so that noses of the first wedge-shaped portion 411N and the second wedge-shaped portion 412N face each other. When viewed on the X-Y plane, each of the first notch portion 411 and the second notch portion 412 may have a quadrangle shape or a diamond shape. Corner portion having quadrangle shapes or diamond shapes may denote the first wedge-shaped portion 411N and the second wedge-shaped portion 412N. The first notch portion 411 may be formed in the cross region 120C of the scribe lane region 120 so that the nose of the first wedge-shaped portion 411N of the first notch portion 411 protrudes toward the second notch portion 412. Some portion of the first notch portion 411 may deviate from the cross region 120C, and may further extend toward the second notch portion 412 along the first scribe lane region 120X.

Referring to FIG. 7, the first notch portion 411 and the second notch portion 412 may be formed in the form of penetration holes that penetrate the organic matter layer 400. The penetration holes through which some portions of the active layer 300 under the organic matter layer 400 are exposed may be formed by removing some portions of the organic matter layer 400. The penetration holes that are formed as described above may be used as the notch portions 410.

Referring to FIGS. 6 and 8, as the notch portions 410 are formed in the portion of the cross region 120C of the scribe lane region 120, the organic matter layer 400 may keep covering a portion of the scribe lane region 120 between the chip regions 110. A portion of the scribe lane region 120 other than the notch portions 410 may still remain covered by the organic matter layer 400. A portion of the active layer 300 that is disposed between the first notch portion 411 and second notch portion 412 of the first scribe lane region 120X may remain covered by the organic matter layer 400. Some portion of the organic matter layer 400 is still maintained between the first notch portion 411 and the second notch portion 412.

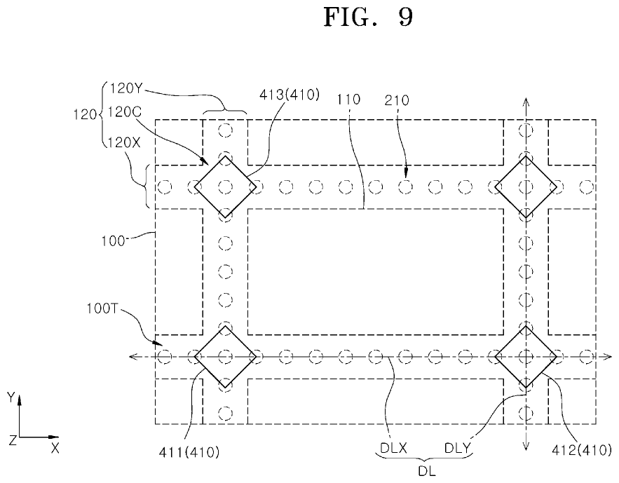

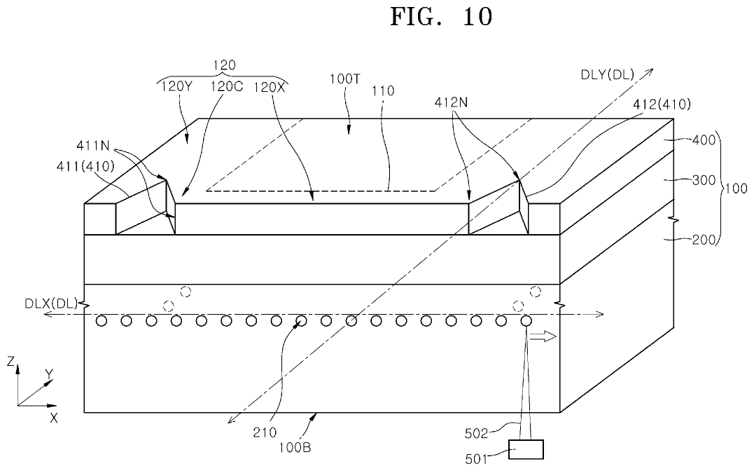

FIGS. 9 and 10 are schematic diagrams illustrating a step of forming the modified patterns 210 in a method of manufacturing a semiconductor chip according to the present teachings. FIG. 9 is a schematic plane view illustrating that the modified patterns 210 have been formed in the substrate 100. FIG. 10 is a schematic perspective view illustrating a step of forming the modified patterns 210 in the substrate 100 by laser irradiation.

Referring to FIGS. 9 and 10, the modified patterns 210 for dicing may be formed within the substrate 100. The modified pattern 210 may be formed as a dicing process using a laser 502, for example, a stealth dicing process is performed. The modified patterns 210 may be formed in some portion of the semiconductor base 200 within the scribe lane region 120. The modified patterns 210 may be formed within the substrate 100 by sequentially irradiating the laser 502 while the laser 502 is sequentially focused on locations at which the modified patterns 210 within the substrate 100 will be formed, by using a laser device 501.

The modified patterns 210 may be formed within the semiconductor base 200 by repeating an operation of irradiating the laser 502 while focusing the laser 502 on the locations at which the modified patterns 210 within the semiconductor base 200 will be formed. The irradiation of the laser 502 that forms the modified patterns 210 may be sequentially performed along the first dicing lines DLX. The modified patterns 210 may be formed in a way to be arranged to form lines along the first dicing lines DLX. The irradiation of the laser 502 that forms the modified patterns 210 may be sequentially performed along the first scribe lane regions 120X. The modified patterns 210 may be formed in a way to be arranged to form lines along the first scribe lane regions 120X.

Furthermore, the modified patterns 210 may be formed in a way to be arranged to form lines along the second dicing lines DLY. The irradiation of the laser 502 that forms the modified patterns 210 may be sequentially performed along the second dicing lines DLY. The irradiation of the laser 502 that forms the modified patterns 210 may be sequentially performed along the second scribe lane regions 120Y. The modified patterns 210 may be formed in a way to be arranged to form lines along the second scribe lane regions 120Y. Some of the modified patterns 210 may be formed to overlap the notch portions 410. As described above, an arrangement of the modified patterns 210 or a layer of the modified patterns 210 may be formed within the substrate 100 or the semiconductor base 200 by laser irradiation. Because such a process may be performed as a stealth dicing process, the layer of the modified patterns 210 may also be denoted as a stealth dicing layer.

The modified patterns 210 may be regenerated to have physical properties different from those of the semiconductor base 200. As some portions of the semiconductor base 200 are modified by the irradiation of the laser 502, the modified patterns 210 may be formed within the semiconductor base 200. If the semiconductor base 200 is constructed to include single crystal silicon, the modified patterns 210 may be regenerated to include amorphous silicon or polycrystalline silicon. As the single crystal silicon is modified into the amorphous silicon or the polycrystalline silicon, stress attributable to a modification of a crystal structure may be induced around the modified patterns 210. The modified patterns 210 may cause stress around the modified patterns 210. The modified patterns 210 may act as elements that generate cracks due to such stress.

The laser 502 may be irradiated so that the plurality of modified patterns 210 is generated at given intervals along the scribe lane region 120. The modified patterns 210 may be formed so that the modified patterns 210 are regularly repeated at given intervals within the semiconductor base 200 of the scribe lane region 120. The modified patterns 210 may be formed to be spaced apart from each other at intervals of several micrometers (μm) to several tens of micrometers (μm). The modified patterns 210 may be spaced apart from each other at intervals of approximately 2 μm to 10 μm. The modified pattern 210 may have a size of several micrometers to several tens of micrometers. The modified pattern 210 may be formed to have an elongated ellipsoidal shape in the thickness direction of the semiconductor base 200.

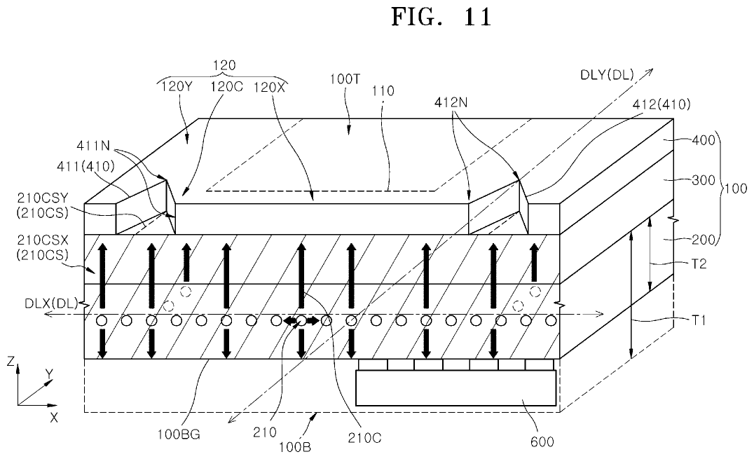

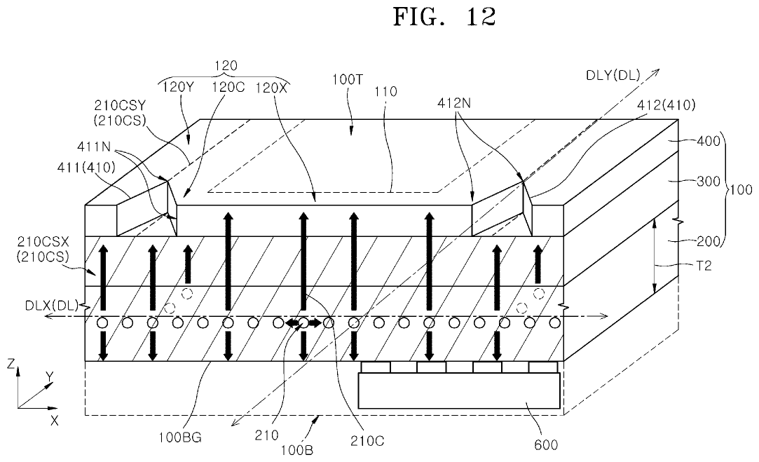

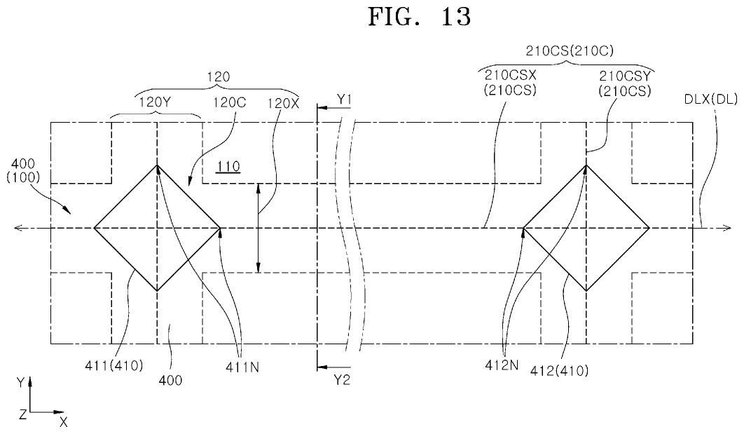

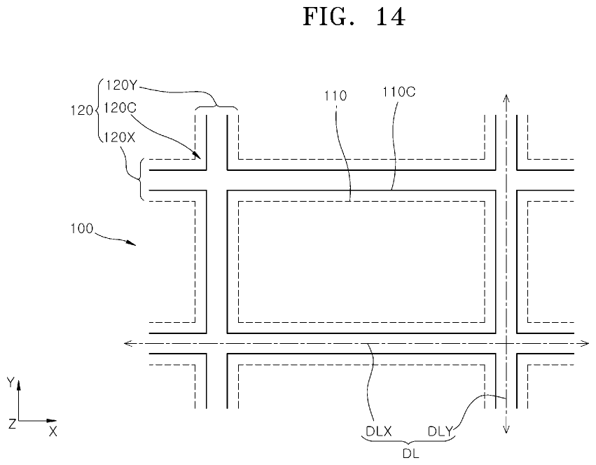

FIGS. 11 to 14 are schematic diagrams illustrating a step of dicing the substrate 100 in a method of manufacturing a semiconductor chip according to the present teachings. FIG. 11 is a schematic perspective view illustrating that cracks 210C are propagated in the substrate 100. FIG. 12 is a schematic perspective view illustrating that the cracks 210C are further propagated toward the organic matter layer 400 of the substrate 100 in FIG. 11. FIG. 13 is a schematic plane view illustrating that the cracks 210C have been propagated in the substrate 100 of FIG. 11. FIG. 14 is a schematic plane view illustrating that the substrate 100 in FIG. 11 has been diced into semiconductor chips 110C.

Referring to FIG. 11, the cracks 210C may occur from the modified patterns 210. The occurred cracks 210C may be grown and induced to be propagated into the substrate 100. As the cracks 210C are propagated, crack sections 210CS that include the cracks 210C may be grown to dice the substrate 100. Stress has occurred around the modified patterns 210. Accordingly, when an external force is applied to the substrate 100, the cracks 210C may occur around the modified patterns 210 due to the external force and the stress. As the cracks 210C are grown, the cracks 210C may be propagated into the substrate 100 or the semiconductor base 200.

The modified patterns 210 are arranged along the dicing lines DL. Accordingly, as the cracks 210C are propagated, the crack sections 210CS may be induced, grown, or propagated along the dicing lines DL. The crack sections 210CS may be constructed as the cracks 210C are gathered or connected together. The crack sections 210CS may induce dicing sections that dice the substrate 100 or may act as the dicing sections. As the modified patterns 210 are arranged along the first dicing lines DLX, first crack sections 210CSX along the first dicing lines DLX may be propagated. Along with the propagation, other modified patterns 210 are arranged along the second dicing lines DLY. Accordingly, second crack sections 210CSY along the second dicing lines DLY may be propagated simultaneously with the first crack sections 210CSX.

Referring back to FIG. 11, the step of dicing the substrate 100 may include a step of back-grinding the substrate 100. A step of grinding the second surface 100B that is opposite to the first surface 100T of the substrate 100 may be performed. In the process of back-grinding the second surface 100B of the substrate 100, an external force may be applied to the substrate 100. The substrate 100 may be back-ground by mounting the substrate 100 on a substrate support (not illustrated) of a grinding apparatus so that the first surface 100T of the substrate 100 is opposite to the substrate support, introducing a grinder 600 into the second surface 100B of the substrate 100, and driving the grinder 600. A protection film (not illustrated) that covers the first surface 100T of the substrate 100 may be introduced. The semiconductor base 200 of the substrate 100 may be processed to have a smaller thickness T2 than an initial thickness T1 by such back-grinding. As the substrate 100 is back-ground by the grinder 600, the substrate 100 may be processed to have a third surface 100BG. As the substrate 100 is back-ground as described above, the substrate 100 may have a smaller thickness than an initial thickness. The back-grinding process may be performed as a process of thinly processing the thickness of the substrate 100.

Referring to FIGS. 12 and 13, the cracks 210C may be propagated even up to the organic matter layer 400 of the substrate 100. The cracks 210C or the crack sections 210CS may be propagated to reach the organic matter layer 400 via the active layer 300 from the semiconductor base 200. The organic matter layer 400 may be a medium into which it is more difficult for the cracks 210C or the crack sections 210CS to be propagated than into the semiconductor base 200 or the active layer 300. It may be difficult for the cracks 210C to be propagated into the organic matter layer 400 because the organic matter layer 400 is composed of an organic material or a polymer material.

The notch portions 410 may act as structures that assist, help, or induce the cracks 210C to be propagated into the organic matter layer 400. The notch portions 410 or the wedge-shaped portions 411N and 412N of the notch portions 410 may provide structures on which stress is concentrated. As the back-grinding process is performed, an external force that is applied to the substrate 100 may provide additional stress around the notch portions 410 or the wedge-shaped portions 411N and 412N of the notch portions 410. The additional stress that is distributed around the notch portions 410 or the wedge-shaped portions 411N and 412N of the notch portions 410 may act as an additional impetus that helps the cracks 210C to be propagated into the organic matter layer 400.

The propagation of the cracks 210C into the organic matter layer 400 can be accelerated because the notch portions 410 are previously formed in the organic matter layer 400 as described above. Accordingly, because the crack sections 210CS may be propagated to shear the organic matter layer 400, a failure that the substrate 100 is not diced because the crack sections 210CS do not shear the organic matter layer 400 can be suppressed or reduced.

The additional stress that has been distributed around the notch portions 410 or the wedge-shaped portions 411N and 412N of the notch portions 410 may be concentrated on nose ends of the wedge-shaped portions 411N and 412N of the notch portions 410. The first notch portion 411 and the second notch portion 412 are formed so that the nose of the first wedge-shaped portion 411N of the first notch portion 411 faces the nose of the second wedge-shaped portion 412N of the second notch portion 412. Accordingly, the first crack section 210CSX may be propagated, expanded, or extended to connect the first notch portion 411 and the second notch portion 412. Because stress has been concentrated on the two nose ends of the wedge-shaped portions 411N and 412N that face each other, the first crack section 210CSX may shear the organic matter layer 400 in a way to connect the first notch portion 411 and the second notch portion 412. Accordingly, a dicing failure that the cracks 210C or the crack sections 210CS deviate from the scribe lane region 120 and are undesirably propagated into the chip region 110 within the organic matter layer 400 can be reduced or suppressed.

As described above, as the cracks 210C or the crack sections 210CS are propagated to shear the organic matter layer 400, the substrate 100 can be diced along the dicing lines DL.

Referring to FIG. 14, the substrate 100 may be expanded and separated into the semiconductor chips 100C along the dicing lines DL. The semiconductor chips 100C may be separated from each other by attaching an expansion film (not illustrated) to the substrate 100 and expanding or pulling the expansion film in the X axis direction and the Y axis direction.

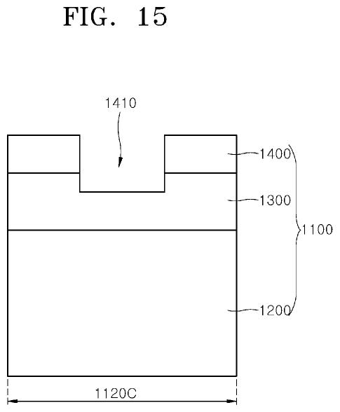

FIG. 15 is a schematic cross-sectional view illustrating a step of forming a notch portion 1410 in a method of manufacturing a semiconductor chip according to the present teachings.

Referring to FIG. 15, when the notch portion 1410 is formed in an organic matter layer 1400 of a substrate 1100, the notch portion 1410 may be formed so that the notch portion 1410 penetrates the organic matter layer 1400 and is further extended into an active layer 1300 under the organic matter layer 1400. In a step of forming a penetration hole that constitutes the notch portion 1410, some portion of the active layer 1300 may be partially removed. As some portion of the active layer 1300 is maintained between the notch portion 1410 and a semiconductor base 1200, some portion of the active layer 1300 that remains between the notch portion 1410 and the semiconductor base 1200 can be blocked.

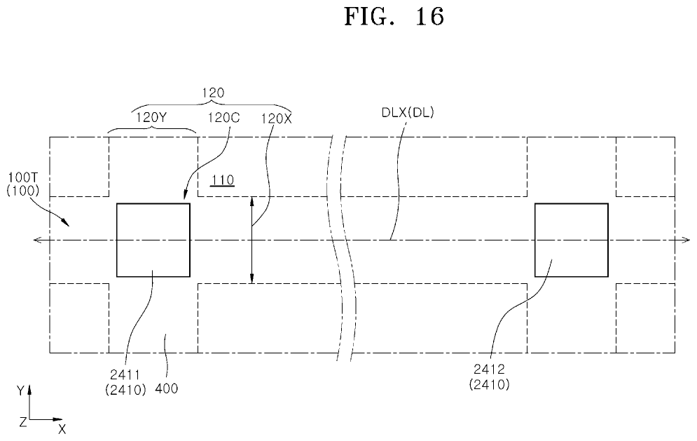

FIG. 16 is a schematic cross-sectional view illustrating a step of forming notch portions 2410 in a method of manufacturing a semiconductor chip according to the present teachings. In FIG. 16, the same reference numerals as those in FIGS. 1 to 14 may denote the same members.

Referring to FIG. 16, when viewed on an X-Y plane, the notch portions 2410 that are formed in the substrate 100 may be formed to have quadrangle shapes. When viewed on the X-Y plane, a first notch portion 2411 and a second notch portion 2412 may be formed to have quadrangle shapes that face each other, respectively.

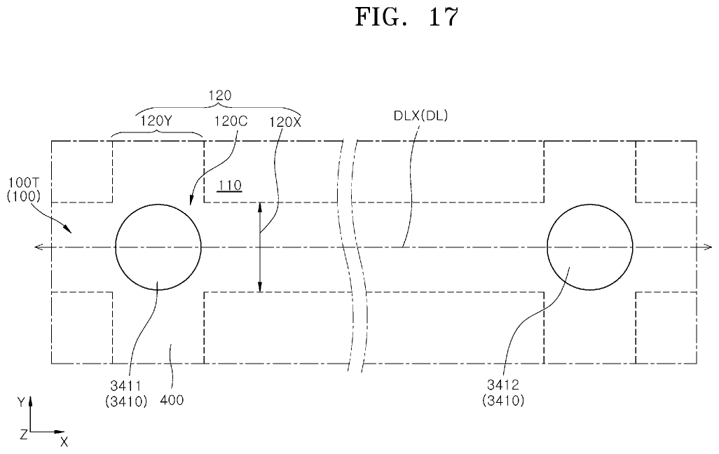

FIG. 17 is a schematic cross-sectional view illustrating a step of forming notch portions 3410 in a method of manufacturing a semiconductor chip according to the present teachings. In FIG. 17, the same reference numerals as those in FIGS. 1 to 14, and 16 may denote the same members.

Referring to FIG. 17, when viewed on an X-Y plane, the notch portions 3410 that are formed in the substrate 100 may be formed to have circular shapes. When viewed on the X-Y plane, a first notch portion 3411 and a second notch portion 3412 may be formed to have circular shapes that face each other, respectively.

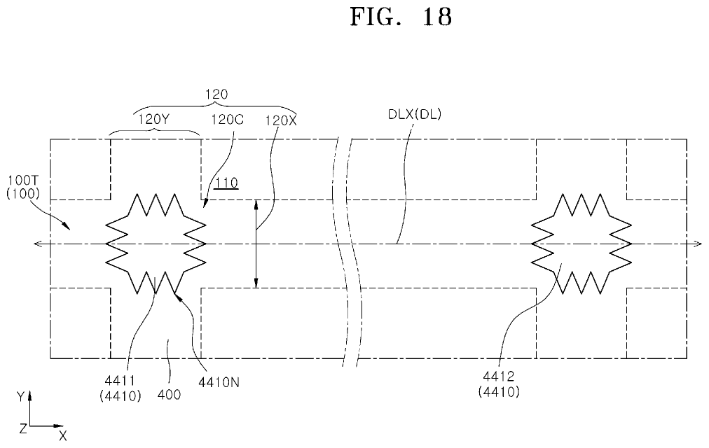

FIG. 18 is a schematic cross-sectional view illustrating a step of forming notch portions 4410 in a method of manufacturing a semiconductor chip according to the present teachings. In FIG. 18, the same reference numerals those in FIGS. 1 to 14, 16, and 17 may denote the same members.

Referring to FIG. 18, when viewed on an X-Y plane, the notch portions 4410 that are formed in the substrate 100 may be formed to have a plurality of wedge-shaped portions 4410N. When viewed on the X-Y plane, the wedge-shaped portions 4410N of the first notch portion 4411 and the second notch portion 4412 may be formed to face each other.

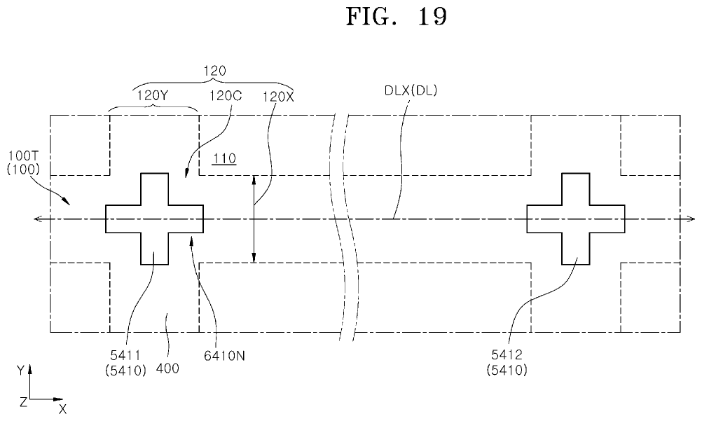

FIG. 19 is a schematic cross-sectional view illustrating a step of forming notch portions 5410 in a method of manufacturing a semiconductor chip according to the present teachings. In FIG. 19, the same reference numerals as those in FIGS. 1 to 14, and 16 to 18 may denote the same members.

Referring to FIG. 19, when viewed on an X-Y plane, the notch portions 5410 that are formed in the substrate 100 may be formed to have cross shapes. When viewed on the X-Y plane, a first notch portion 5411 and a second notch portion 5412 may be formed to have cross shapes, respectively, which are extended so that branch portions 5410N having a cross shape face each other.

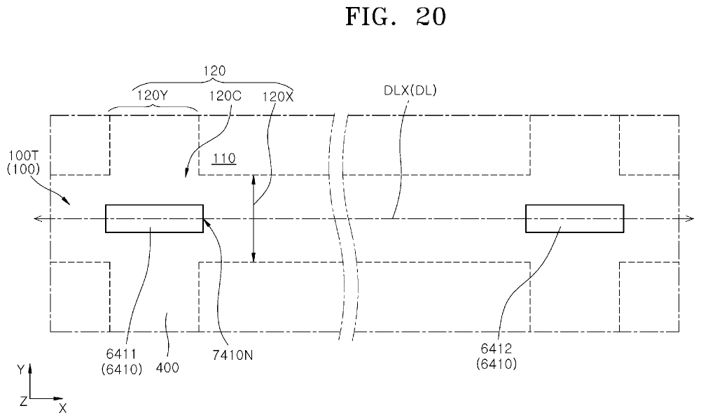

FIG. 20 is a schematic plane view illustrating a step of forming notch portions 6410 in a method of manufacturing a semiconductor chip according to the present teachings. In FIG. 20, the same reference numerals as those in FIGS. 1 to 14 and 16 to 19 may denote the same members.

Referring to FIG. 20, when viewed on an X-Y plane, the notch portions 6410 that are formed in the substrate 100 may be formed to have oblong shapes. When viewed on the X-Y plane, a first notch portion 6411 and a second notch portion 6412 may be formed to have shapes that are extended so that long-axis ends 7410N that belong to the first notch portion 6411 and the second notch portion 6412 and that have the oblong shapes face each other, respectively. The oblong shape may have a shape that is relatively elongated in a direction in which the first dicing line DLX is extended. The oblong shape may be modified to have a shape that is relatively elongated in a direction that is perpendicular to the direction in which the first dicing line DLX is extended.

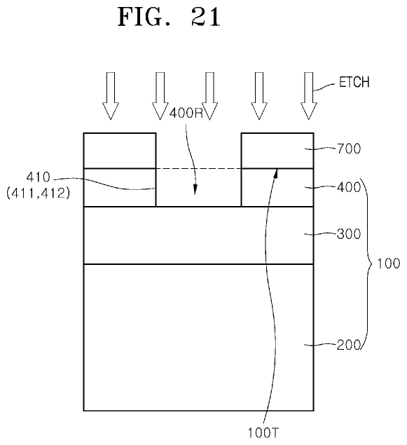

FIG. 21 is a schematic cross-sectional view illustrating a step of forming the notch portions 410 in a method of manufacturing a semiconductor chip according to the present teachings. FIG. 21 is a schematic cross-sectional view illustrating an example of a method of forming the notch portion 410 in FIG. 5.

Referring to FIGS. 5 and 21, the notch portions 410 that include the first and second notch portions 411 and 412 may be formed in the organic matter layer 400 by a selective etch process. A mask pattern 700 may be formed on the first surface 100T of the substrate 100. The mask pattern 700 may be formed through process steps of coating a resist material on the organic matter layer 400 and forming a resist pattern by exposing and developing a layer of the resist material. A selective etch process that uses the mask pattern 700 as an etch mask may be performed. Some portions of the first surface 100T of the substrate 100, which are exposed by the mask pattern 700, may be removed by etching. The notch portion 410 may be formed in the form of a penetration hole that penetrates the organic matter layer 400 by removing some portion 400R of the organic matter layer 400 of the substrate 100, which is exposed by the mask pattern 700, by etching. An etch process may be further performed so that some portion of the active layer 300, which is exposed under the notch portion 410, is removed.

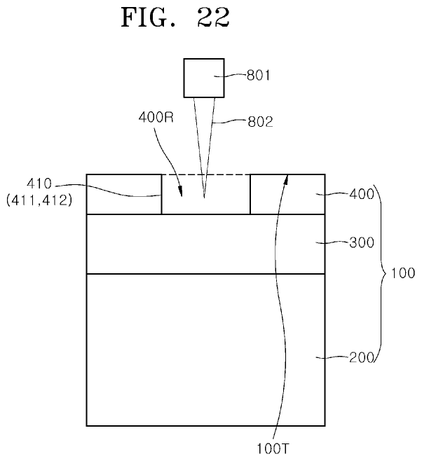

FIG. 22 is a schematic cross-sectional view illustrating a step of forming the notch portion 410 in a method of manufacturing a semiconductor chip according to the present teachings. FIG. 22 is a schematic cross-sectional view illustrating another example of a method of forming the notch portion 410 in FIG. 5.

Referring to FIGS. 5 and 22, the notch portions 410 that include the first and second notch portions 411 and 412 may be formed in the organic matter layer 400 by a laser ablation process. Some portions of the first surface 100T of the substrate 100 may be removed by ablation using a laser. The notch portion 410 may be formed in the form of a penetration hole that penetrates the organic matter layer 400 by removing some portion 400R of the organic matter layer 400 of the substrate 100 by ablation using a laser. The some portion 400R of the organic matter layer may be removed by irradiating an ablation laser 802 to the organic matter layer 400 by using a laser ablation apparatus 801.

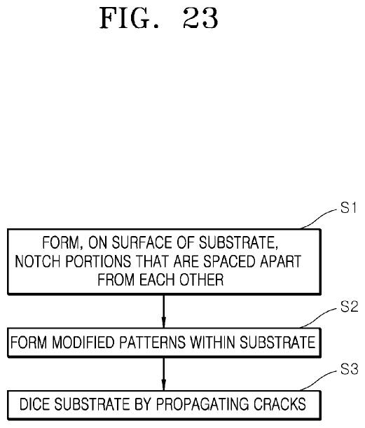

FIG. 23 is a process flowchart illustrating a method of manufacturing a semiconductor chip according to the present teachings.

Referring to FIG. 23, the method of manufacturing a semiconductor chip may include step S1 of forming, on a surface of the substrate, the notch portions that are spaced apart from each other, step S2 of forming the modified patterns within the substrate, and step S3 of dicing the substrate by propagating cracks. Step S1 of forming the notch portions may include a step of forming, on the first surface 100T of the substrate 100, the first notch portion 411 and the second notch portion 412 that are spaced apart from each other along the first dicing line DL, as proposed in FIG. 5. Step S2 of forming the modified patterns within the substrate may include a step of forming the modified patterns 210 in a way to be arranged along the first dicing line DLX, as proposed in FIG. 10. Step S3 of dicing the substrate by propagating the cracks may include a step of propagating the crack sections 210CS into the substrate 100 by generating and propagating the cracks 210C and making the crack sections 210CS act as dicing sections that dice the substrate 100, as proposed in FIGS. 11 and 12.

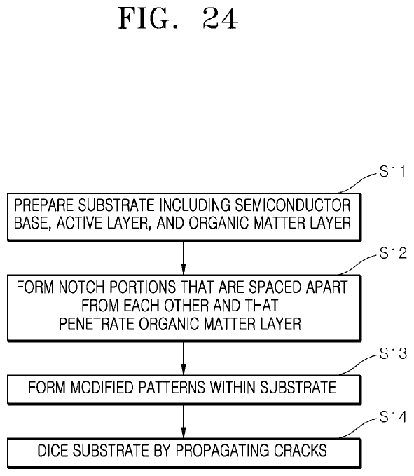

FIG. 24 is a process flowchart illustrating a method of manufacturing a semiconductor chip according to the present teachings.

Referring to FIG. 24, the method of manufacturing a semiconductor chip may include step S11 of preparing the substrate including the semiconductor base, the active layer, and the organic matter layer, step S12 of forming the notch portions that are spaced apart from each other and that penetrate the organic matter layer, step S13 of forming the modified patterns within the substrate, and step S14 of dicing the substrate by propagating the cracks. Step S11 of preparing the substrate may include a step of forming the substrate 100 by sequentially forming the active layer 300 and the organic matter layer 400 on the semiconductor base 200, as proposed in FIG. 10. The first and second scribe lane regions 120X and 120Y may intersect in the semiconductor base 200. Step S12 of forming the notch portions may include a step of forming the first notch portion 411 and the second notch portion 412 that are spaced apart from each other in the first scribe lane region 120X of the substrate 100 and that penetrate the organic matter layer 400. Step S13 of forming the modified patterns within the substrate may include a step of forming the modified patterns 210 in a way to be arranged within the semiconductor base 200 along the first scribe lane region 120X, as proposed in FIG. 10. Step S14 of dicing the substrate may include a step of propagating the crack sections 210CS into the substrate 100 by generating and propagating the cracks 210C and making the crack sections 210CS act as dicing surfaces that dice the substrate 100, as proposed in FIGS. 11 and 12.

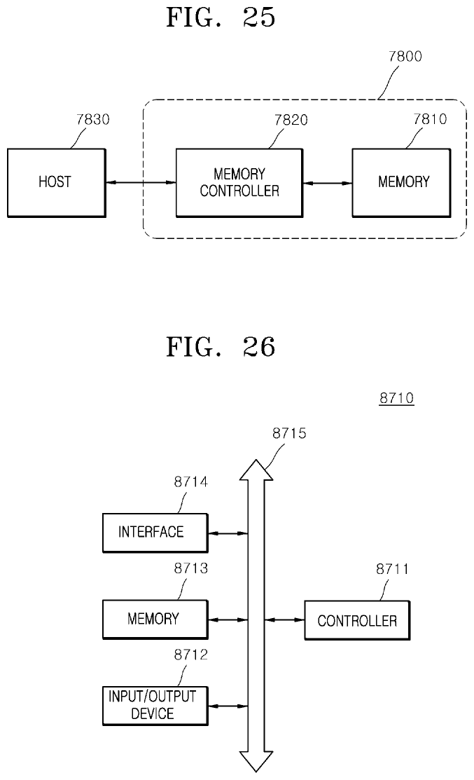

FIG. 25 is a block diagram illustrating an electronic system including a memory card 7800 employing at least one semiconductor chip manufactured according to the present teachings. The memory card 7800 includes a memory 7810 such as a nonvolatile memory device, and a memory controller 7820. The memory 7810 and the memory controller 7820 may store data or read out the stored data. At least one of the memory 7810 and the memory controller 7820 may include at least one semiconductor package manufactured according to the present teachings.

The memory 7810 may include a nonvolatile memory device to which the technology of the present disclosure is applied. The memory controller 7820 may control the memory 7810 such that stored data is read out or data is stored in response to a read/write request from a host 7830.

FIG. 26 is a block diagram illustrating an electronic system 8710 including at least one semiconductor chip manufactured according to the present teachings. The electronic system 8710 may include a controller 8711, an input/output device 8712, and a memory 8713. The controller 8711, the input/output device 8712, and the memory 8713 may be coupled with one another through a bus 8715 providing a path through which data move.

In an embodiment, the controller 8711 may include one or more microprocessor, digital signal processor, microcontroller, and/or logic device capable of performing the same functions as these components. The controller 8711 or the memory 8713 may include at least one semiconductor package manufactured according to the present disclosure. The input/output device 8712 may include at least one selected among a keypad, a keyboard, a display device, a touch screen and so forth. The memory 8713 is a device for storing data. The memory 8713 may store data and/or commands to be executed by the controller 8711, and the like.

The memory 8713 may include a volatile memory device such as a DRAM and/or a nonvolatile memory device such as a flash memory. For example, a flash memory may be mounted to an information processing system such as a mobile terminal or a desktop computer. The flash memory may constitute a solid-state disk (SSD). In this case, the electronic system 8710 may stably store a large amount of data in a flash memory system.

The electronic system 8710 may further include an interface 8714 configured to transmit and receive data to and from a communication network. The interface 8714 may be a wired or wireless type. For example, the interface 8714 may include an antenna or a wired or wireless transceiver.

The electronic system 8710 may be realized as a mobile system, a personal computer, an industrial computer or a logic system performing various functions. For example, the mobile system may be any one of a personal digital assistant (PDA), a portable computer, a tablet computer, a mobile phone, a smart phone, a wireless phone, a laptop computer, a memory card, a digital music system and an information transmission/reception system.

If the electronic system 8710 is an equipment capable of performing wireless communication, the electronic system 8710 may be used in a communication system using a technique of CDMA (code division multiple access), GSM (global system for mobile communications), NADC (north American digital cellular), E-TDMA (enhanced-time division multiple access), WCDMA (wideband code division multiple access), CDMA2000, LTE (long term evolution) or Wibro (wireless broadband Internet).

A person having ordinary knowledge in the art to which the present teachings pertain will understand that the present teachings may be implemented in a modified form without departing from an intrinsic characteristic of the present disclosure. Accordingly, the disclosed methods should be considered from a descriptive viewpoint, not from a limitative viewpoint. The range of the present disclosure is described in the claims not the aforementioned description, and all differences within an equivalent range thereof should be construed as being included in the present disclosure.

What is claimed is:

1. A method of manufacturing a semiconductor chip, comprising:
forming, on a first surface of a substrate, a first notch portion and a second notch portion that are spaced apart from each other along a first dicing line;
forming modified patterns within the substrate; and
dicing the substrate by propagating cracks into the substrate from the modified patterns.

2. The method of claim 1, wherein the substrate comprises:
a semiconductor base;
an organic matter layer that is formed over the semiconductor base; and
an active layer that is formed between the organic matter layer and the semiconductor base,
wherein forming the first notch portion and the second notch portion comprises forming penetration holes that penetrate the organic matter layer by removing some portions of the organic matter layer.

3. The method of claim 2, wherein the organic matter layer comprises poly(imide-isoindoloquinazolinedione).

4. The method of claim 2, wherein forming the penetration holes comprises partially removing some portion of the active layer.

5. The method of claim 2, wherein the active layer comprises a plurality of conductive layers and a plurality of interlayer insulating layers.

6. The method of claim 1, further comprising forming, on the first surface of the substrate, a third notch portion that is spaced apart from the first notch portion along a second dicing line that intersects the first dicing line.

7. The method of claim 1, wherein forming the first notch portion and the second notch portion comprises:
forming a mask pattern on the first surface of the substrate; and
etching portions of the first surface of the substrate which are exposed by the mask pattern.

8. The method of claim 1, wherein forming the first notch portion and the second notch portion comprises ablating some portions of the first surface of the substrate by using a laser.

9. The method of claim 1, wherein the first notch portion and the second notch portion have wedge-shaped portion noses which face each other.

10. The method of claim 1, wherein the first notch portion and the second notch portion have quadrangle shapes, circular shapes, or oblong shapes that face each other.

11. The method of claim 1, wherein the first notch portion and the second notch portion have cross shapes that face each other.

12. The method of claim 1, wherein the modified patterns are formed to be arranged in a line along the first dicing line.

13. The method of claim 1, wherein forming the modified patterns comprises irradiating, with a laser, portions of the substrate at which the modified patterns are to be disposed.

14. The method of claim 1, wherein dicing the substrate comprises grinding a second surface that is opposite to the first surface of the substrate.

15. A method of manufacturing a semiconductor chip, comprising:
forming a substrate which comprises a semiconductor base in which first and second scribe lane regions intersect, an active layer that is formed on the semiconductor base, and an organic matter layer;
forming a first notch portion and a second notch portion that are spaced apart from each other in the first scribe lane region and that penetrate the organic matter layer;
forming modified patterns within the semiconductor base along the first scribe lane region; and
dicing the substrate by propagating cracks into the substrate from the modified patterns.

16. The method of claim 15, wherein the first notch portion and the second notch portion are formed to extend into the active layer.

17. The method of claim 15, wherein the first notch portion and the second notch portion are disposed at portions in which the first and second scribe lane regions intersect.

18. The method of claim 15, further comprising forming, in a second scribe lane region, a third notch portion that is spaced apart from the first notch portion.

19. The method of claim 15, wherein the organic matter layer comprises poly(imide-isoindoloquinazolinedione).

20. The method of claim 15, wherein dicing the substrate further comprises grinding a surface of the semiconductor base, which is opposite to the organic matter layer.

21. The method of claim 15, wherein the active layer comprises a plurality of conductive layers and a plurality of interlayer insulating layers.

22. The method of claim 15, wherein forming the first notch portion and the second notch portion comprises:
forming a mask pattern on the organic matter layer; and
removing portions of the organic matter layer which are exposed by the mask pattern.

23. The method of claim 15, wherein forming the first notch portion and the second notch portion comprises ablating some portions of the organic matter layer by using a laser.

24. The method of claim 15, wherein the first notch portion and the second notch portion have wedge-shaped portion noses which face each other.

25. The method of claim 15, wherein the first notch portion and the second notch portion have quadrangle shapes, circular shapes, or oblong shapes that face each other.

26. The method of claim 15, wherein the first notch portion and the second notch portion have cross shapes that face each other.

27. The method of claim 15, wherein forming the modified patterns comprises irradiating, with a laser, portions of the semiconductor base at which the modified patterns are to be disposed.
